(19) United States
(12) Patent Application Publication
(10) Pub. No.: US 2013/0051080 A1
(43) Pub. Date: Feb. 28, 2013

(54) POWER STATION ASSEMBLY

(71) Applicants: Benjamin Luke VAN DER LINDE, Heatherton (AU); David Leigh SCRIMSHAW, Heatherton (AU); Paul Francis CONNOR, Heatherton (AU); Paul MILLER, Heatherton (AU); Ben EYERS, Heatherton (AU); Sion NETZLER, Heatherton (AU); Lucas LASTMAN, Heatherton (AU)

(72) Inventors: Benjamin Luke VAN DER LINDE, Heatherton (AU); David Leigh SCRIMSHAW, Heatherton (AU); Paul Francis CONNOR, Heatherton (AU); Paul MILLER, Heatherton (AU); Ben EYERS, Heatherton (AU); Sion NETZLER, Heatherton (AU); Lucas LASTMAN, Heatherton (AU)

(73) Assignee: DEMAIN TECHNOLOGY PTY LTD, Victoria (AU)

(21) Appl. No.: 13/594,229

(22) Filed: Aug. 24, 2012

Related U.S. Application Data
(63) Continuation of application No. PCT/AU2011/000210, filed on Feb. 25, 2011.

(30) Foreign Application Priority Data
Feb. 25, 2010 (AU) 2010900807
Feb. 25, 2010 (AU) 2010900808
Feb. 25, 2010 (AU) 2010900809
Feb. 26, 2010 (AU) 2010900831
Nov. 29, 2010 (AU) 2010905259

(51) Int. Cl. H01R 13/72; H05K 7/18; H01R 33/00

(52) U.S. Cl. 362/649; 439/501; 362/640; 312/107

(57) ABSTRACT

The present invention provides an assembly for providing electrical power to an electrical device. The assembly includes a receptacle including an electrical connector for connection to a power supply, a length of an electrical cable that is contained within the receptacle and that is coupled to the electric connector, wherein the length of electrical cable is retractably extendable from within the receptacle. In an embodiment, the electrical cable is electrically connectable to a mains power supply to transmit electrical power from the supply to one or more electrical connectors mounted to the receptacle. In another embodiment, the assembly includes a releasably connectable power distribution board and in another embodiment the assembly includes a releasably connectable light emitting device.

### CROSS REFERENCE TO RELATED APPLICATION

This application is a continuation application based on PCT Patent Application No. PCT/AU2011/000210, filed Feb. 25, 2011, whose priority is claimed on Australian Patent Application Nos. 2010900808 filed Feb. 25, 2010, 2010900807 filed Feb. 25, 2010, 201000809 filed Feb. 25, 2010, 2010900831 filed Feb. 26, 2010 and 2010905259 filed Nov. 29, 2010, the entire content of which is hereby incorporated by reference.

### FIELD OF THE INVENTION

The present invention relates to the field of electrical connectors. In particular, the present invention relates to a power distribution board assembly for supplying power to a plurality of electrically powered devices.

### BACKGROUND OF THE INVENTION

It is to be appreciated that any discussion of documents, devices, acts or knowledge in this specification is included to explain the context of the present invention. Further, the discussion throughout this specification comes about due to the realisation of the inventor and/or the identification of certain related art problems by the inventor. Moreover, any discussion of material such as documents, devices, acts or knowledge in this specification is included to explain the context of the invention in terms of the inventor's knowledge and experience and, accordingly, any such discussion should not be taken as an admission that any of the material forms part of the prior art base or the common general knowledge in the relevant art in Australia, or elsewhere, on or before the priority date of the disclosure and claims herein.

Existing power boards or power distribution boards typically include a housing having a plurality of electrical connectors associated with a plurality of electrical sockets that are configured to respectively electrically connect to an electrical plug attached to an end of a power cord extending from an electrically powered device. The power board typically includes a power cable attached to the housing and having an electrical plug for connection to an electrical supply outlet. The electrical cord typically enters the housing and is connected to each of the plurality of electrical connectors of the plurality of electrical sockets in the housing. Accordingly, when the electrical cord of the power board is connected to a mains electrical supply the electrical connectors of the electrical plugs of one or more electrically powered devices can be plugged into a respective one of the electrical sockets of the power board to thereby supply electrical power to the one or more electrically powered devices.

It is often desirable to be able to provide a means for providing an electrical power supply to one or more electrical devices at locations that are remote from a power supply outlet. This is often the case where the electrically powered device is a hand held power tool where work to be carried out by the power tool may be located at a position that is quite remote from any power supply outlet. Furthermore, in circumstances in which a user wishes to perform work, such as with a hand held power tool but not necessarily so, at a position remote from a power supply outlet it is often desirable for the user to have other means at their disposal for assisting in carrying out such work. For example, where work is to be carried out in a poorly lit environment a user may require some means of providing light in the area in which work is to be carried out.

### SUMMARY OF THE INVENTION

Accordingly, the present invention seeks to ameliorate the problems set out above by providing, in a first aspect, an carry cabinet for providing electrical power to an electrical device, the carry cabinet including:
a receptacle including an electrical connector for connection to a power supply;
a length of an electrical cable that is contained within the receptacle and that is coupled to the electrical connector,
wherein the length of electrical cable is retractably extendable from within the receptacle.

In a preferred embodiment, the electrical cable being electrically connectable to an electrically powered device to transmit electrical power from the power supply to the device.

In another embodiment, the length of electrical cable is wound around a reel contained within the receptacle wherein the cable can be unwound from the reel to extend from the receptacle and wound around the reel to thereby retract the cable into the receptacle.

In yet another embodiment, the carry cabinet further includes a power distribution board including a housing having a plurality of electrical connectors for connection with one or more electrically powered devices and a length of electrical cable including an electrical connector for connection to a power supply.

In an embodiment, the power distribution board and the receptacle are releasably connectable together and the receptacle includes an electrical connector that is connectable to the length of electrical cable of the power distribution board to supply electrical power thereto.

In another embodiment, the receptacle includes one or more locking members that are configured to releasably lock the housing of the power distribution board to the receptacle.

In yet another embodiment, the locking member includes a rotatable abutment surface that is receivable through an opening in the housing of the power distribution board and is rotatable relative to the opening to a position in which the abutment surface abuts against a portion of the housing immediately adjacent to the opening to thereby lock the housing to the receptacle.

In another embodiment, the carry cabinet further includes an electrically powered light emitting device that is releasably connectable to the receptacle and includes a length of electrical cable including an electrical connector for connection to a power supply.

In an embodiment, the carry cabinet further includes an electrical connector that is connectable to the length of electrical cable of the electrically powered light emitting device to supply electrical power thereto.

In another embodiment, the light emitting device includes a housing having a base member containing a light source and a transparent cover member connected to the base member for covering the light source and allowing light to pass therethrough.

In yet another embodiment, the light emitting device housing includes a stand member pivotally attached to the base member for maintaining the light emitting device in an upright position on a surface.

In still yet another embodiment, the receptacle includes one or more locking members for releasably locking the light emitting device to the receptacle.

In a further embodiment, the locking member includes a rotatable abutment surface that is receivable through an opening in the housing of the light emitting device and is rotatable relative to the opening to a position in which the abutment surface abuts against a portion of the housing immediately adjacent to the opening to thereby lock the housing to the receptacle.

In a preferred embodiment, the receptacle includes means for releasable attachment of the receptacle to a support fixed to an upright surface.

Preferably, the receptacle includes an opposing pair of inwardly curved members for receiving a pair of outwardly curved surfaces of the support therebetween wherein the weight of the carry cabinet is substantially supported by engagement between an upper on of the inwardly curved surfaces of the receptacle and an upper one of the outwardly curved surfaces of the support.

More preferably, the receptacle pivots about the engaged upper one of the inwardly curved surfaces and the upper one of the outwardly curved surfaces until a lower one of the inwardly curved surfaces of the receptacle engages the lower one of the outwardly curved surfaces of the support in a releasably locking arrangement.

Where used herein the term ‘assembly’ is understood to by synonymous with the term ‘carry cabinet’.

In a further embodiment of the present invention there is provided a carry cabinet adapted for providing electrical power to a handheld power tool, the carry cabinet including:
an electrical connector for connection to a power supply;
an electrical cable that is contained within the carry cabinet, the electrical cable having a first end for connection to the electrical connector and a second end that is electrically connectable to the handheld power tool to transmit electrical power from the power supply to the power tool;
   wherein the carry cabinet includes a mounting mean for releasably mounting the cabinet on a frame.

In a preferred embodiment the carry cabinet is portable. Thus the carry cabinet may be stored on the frame, and can be readily released and carried to where it is needed. The carry cabinet may be releasably mounted by any convenient mounting means, such as a latch that allows the carry cabinet can be changed between a mounted and a demounted configuration respectively by engaging and disengaging the latch between the carry cabinet and the frame.

In a particularly preferred embodiment the carry cabinet further includes an electrically powered light emitting device that is releasably connectable to the carry cabinet. Thus the carry cabinet is a mobile source of electricity and illumination that can placed in the most convenient location.

Furthermore, the carry cabinet of the present invention may form part of a storage system for storing devices, the system typically including:
a frame for demountably supporting multiple carry cabinets,
at least one carry cabinet according to the present invention,
at least one carry cabinet adapted to receive a handheld power tool, wherein said handheld power tools can be removably inserted through a port in their respective carry cabinet while said multiple carry cabinets are mounted on the frame,

characterised in that,
said devices can be transported in their respective carry cabinets when each of said carry cabinets are demounted from the frame and electrically connected to the electrical cable of the carry cabinet of the present invention.

### BRIEF DESCRIPTION OF THE DRAWINGS

The present invention will now be described in more detail with reference to the following figures. The following figures represent embodiments of the invention in the form of a power station assembly for connection with one more electrical devices and a power supply for supplying power to the electrical devices.

FIG. 1 illustrates a perspective view of the power station assembly including a receptacle containing a power board module, a light emitting device and a retractable power cord.

FIG. 2 illustrates a perspective view of the power station assembly of FIG. 1 with part of the receptacle removed to illustrate the light emitting device module and the retractable power cord located within the receptacle.

FIG. 3 illustrates a perspective view of the power station assembly of FIG. 1 with part of the receptacle removed and the light emitting device module removed to illustrate the retractable power cord and the power board module located within the receptacle.

FIG. 4 illustrates a power board module of the power station assembly of FIG. 1.

FIG. 5 illustrates a forward perspective view of the light emitting device module of the power station assembly of FIG. 1.

FIG. 6 illustrates a rearward perspective review light emitting device module of the power station assembly of FIG. 1.

FIG. 7 illustrates a forward perspective view of a support that is configured to be mounted to an upright surface, such as a wall, and that is configured for releasable attachment with the power station assembly of FIG. 1.

FIG. 8 illustrates a perspective view the support of FIG. 7 with the power station assembly of FIG. 1 attached thereto.

### DETAILED DESCRIPTION

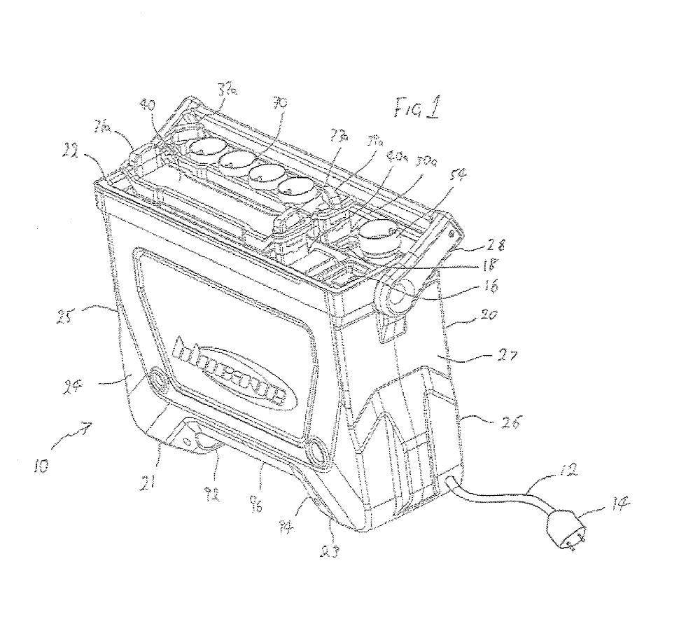

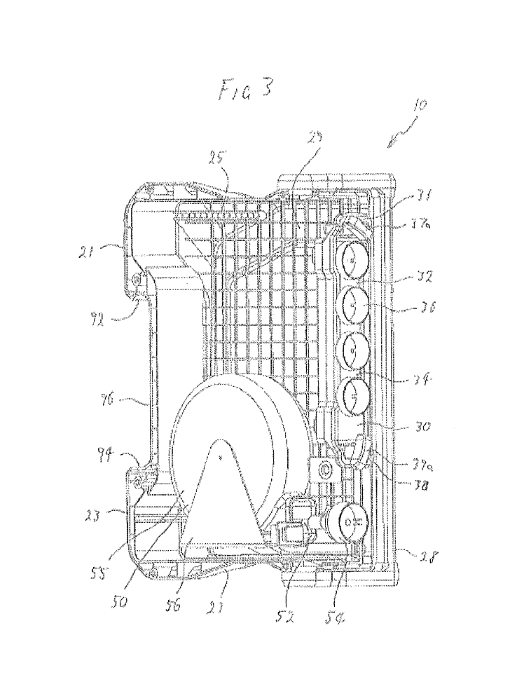

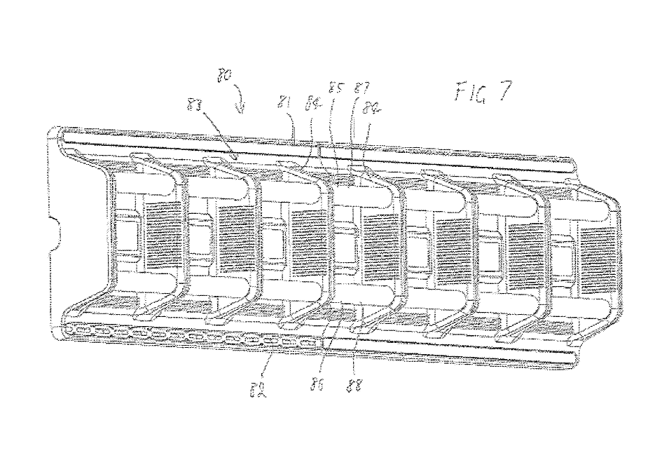

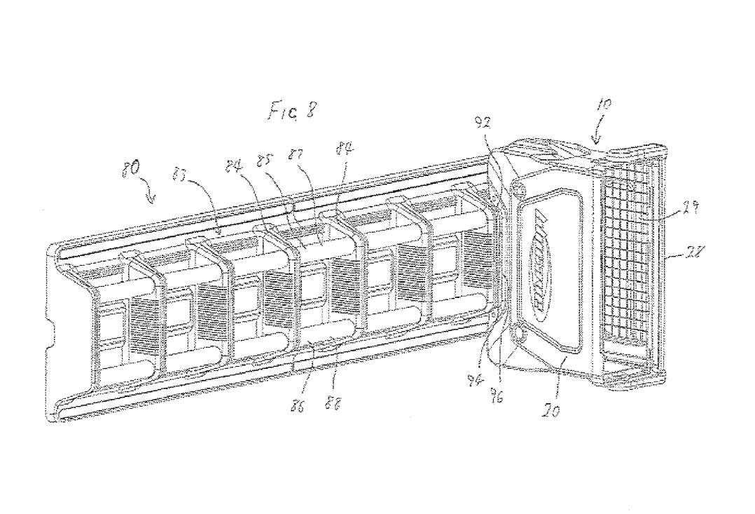

Referring to FIGS. 1 to 3, there is shown a power station assembly 10 in accordance with an embodiment of the invention. The assembly 10 broadly includes a receptacle 20 that is configured for releasably attachment to a support, as illustrated in FIGS. 7 and 8, wherein the support 80 is attached to an upright surface such as a wall surface. The power station assembly 10 further includes a power board module 30 that is releasably connectable to the receptacle 20 and a light emitting device module 40 that is also releasably connectable to the receptacle 20. The power station assembly 10 further includes a length of power cord 50 that is arranged to retractably extend from within the receptacle 20 of the power station assembly 10. The power station assembly 10 further includes a power supply cord 12 in the form of a length of electrically conductive cable including a plug type electrical connector 14 that extends from the receptacle 20 for connection to a power supply outlet, such as a mains power supply outlet, wherein the power supply cord is electrically connected to a number of components of the power station assembly 10 to supply power thereto.

In use, the power station assembly 10 can facilitate supply of electrical power at a location remote from a power supply outlet, such as a mains power supply outlet, at which a user may require power for one or more electrical devices. To achieve this, the power supply cord 12 may be withdrawn from within the receptacle 20 and connected to a power supply located proximally to the power station assembly 10. The retractable power cord 50 may then be withdrawn from within the receptacle 20 and brought to a location remote from the power station assembly 10, and the power supply outlet, and can be electrically connected to an electrically powered device or to the power board module 30 which is thereby capable of connection to one or more electrically powered devices and for supplying power thereto. Furthermore, the light emitting device module 40 can be removed from the receptacle 20 and can be connected to the retractable power cord 50 or the power board module 30 for casting light in a work area or on a work surface.

Referring to FIGS. 1 to 3, 7 and 8, the receptacle 20 includes a base portion 21 that includes a base wall 23, a pair of opposite side walls 24, 26 upstanding from the base wall 23 and a pair of opposite end walls 25, 27 upstanding from the base wall 23 and extending between and to each of the side walls 24, 26. Accordingly, the base wall 23, side walls 24, 26 and end walls 25, 27 of the base portion 21 generally form a box shaped member including an internal cavity 29. Edges of the end walls 25, 27 and the side walls 24, 26 located distally from the base wall 23 define an opening to the cavity 29. The opening is covered by a fascia 22. The receptacle 20 further includes a handle member 28 that is pivotally connected to the end walls 25, 27 of the base portion 21. The handle member 28 is configured to be gripped by a user to transport the power station assembly 10 to a desired location.

The power supply cord 12 is electrically connected to a main on-off switch 16. The main on-off switch 16 is electrically connected to the retractable power cord 50 and to at least two more electrical connectors (not shown) mounted to the fascia 22 of the receptacle 20. The main on-off switch 16 is manually operable for selectively supplying electrical power from a power outlet via the power supply cord 12 to the retractable power cord 50 and the at least two more electrical connectors (not shown) mounted to the fascia 22. The assembly 10 further includes a manually resettable circuit breaker 18 that is operable for cutting the supply of electrical power from the power outlet via the power supply cord 12 to the retractable power cord 50 and/or the at least two more electrical connectors (not shown) mounted to the fascia 22 in the event that the current flow exceeds a predetermined threshold.

The retractable power cord 50 includes a length of electrically conductive cable 52 including a plug type electrical connector 54 electrically connected to one end of the cable 52. The cable 52 is wound around a reel 55 that is mounted to a bracket 56. The reel 55 is fixed within the cavity 29 of the receptacle 20 by way of the bracket 56 being fixed to the base portion 21 of the receptacle 20. The reel 55 is capable of rotating relative to the bracket 56 to enable the cable 52 to be unwound and drawn therefrom such that any desirable length of the cable 52 may be drawn from the receptacle 20 such that the connector 54 can be connected to an electrically powered device and/or to the power distribution board 30 at a location remote from the power station assembly 10. The reel 55 is configured to selectively retract the cable 52 by rotating relative to the bracket 56 when it is required by a user to retract the cable 52. The other end of the cable 52 is electrically connected to the power supply cable 12. Accordingly, when the power supply cable 12 is connected to a power supply outlet electrical power can be supplied via the retractable power cord 50 to an electrically powered device and/or to the power distribution board 30 at a location remote from the power station assembly 10.

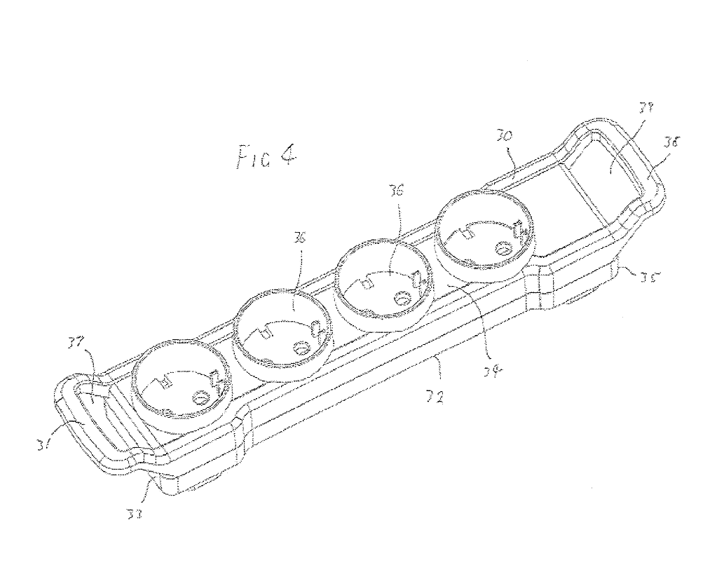

Referring to FIGS. 1, 3 and 4, the power board module 30 includes a housing 32 that is elongated and includes a first end 33, a second end 35 and a face panel 34 extending between the first and second ends 33, 35. The face panel 34 includes a plurality of electrical connector portions 36 mounted therein. An electrically conductive cable (not shown) extends from the housing 32 that can be electrically connected to an electrical connector (not shown) mounted in the fascia 22 of the receptacle 20 or to connector 54 of the retractable power cord 50. The cable extending from the housing 32 of the power board module 30 is electrically connected to each of the electrical connector portions 36 such that when the connector 14 of the power supply cable 12 is connected to a power supply each of the connector portions 36 of the power board module 30 are operable for connection with an electrical connector of an electrically powered device and for suppling electrical power to the device.

The power board module 30 is configured to be received within a power board module receiving opening 30A within the facia 22 of the receptacle 20. The power board module 30 includes first and second openings 37, 39 respectively located at the first and second ends 33, 35 of the housing 32. When the housing 32 is fitted within the power board module receiving opening 30A of the facia 22 a pair of locking members 37A, 39A are respectively received within one of the openings 37, 39. The locking members 37A, 39A are in the form of rotatable locking knobs that each include an abutment surface that is configured to abut against one of a pair of abutment surfaces 31, 38 located immediately adjacent to each of the openings 37, 39 when the locking knob is rotated to a appropriate position to thereby lock the power board module 30 within the module opening 30A of the receptacle 20. Rotation of the locking members 37A, 39A causes the abutment surfaces thereof to be disengaged from the abutment surfaces 31, 38 adjacent to the openings 37, 39 to enable the power board module 30 to be removed within the module opening 30A.

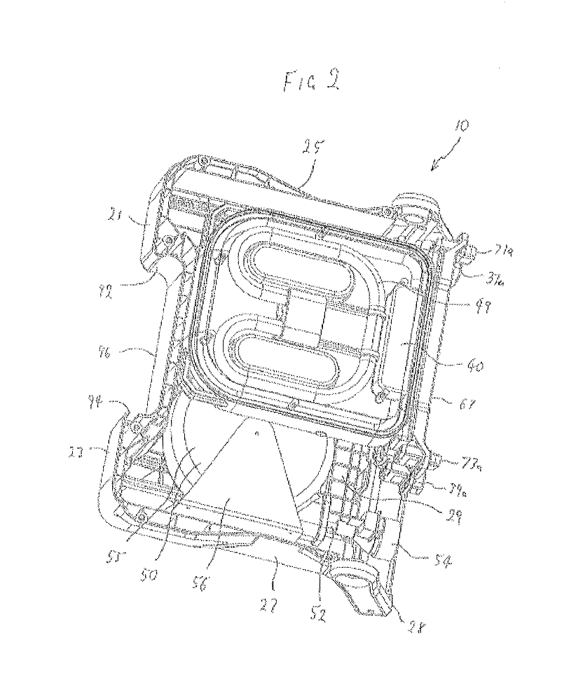

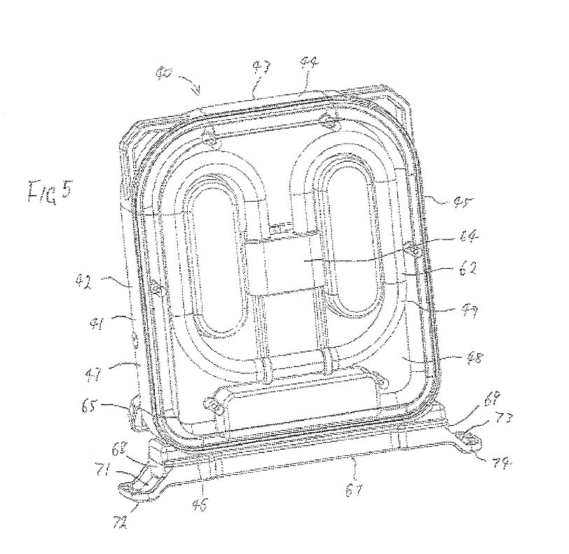

Referring to FIGS. 2, 5 and 6, the light emitting device module 40 includes a housing 42 comprised of a base housing 41 including a base panel 43 and four side panels 44, 45, 46, 17 upstanding from the base panel 43 to define a cavity there within. Mounted within the cavity within the base housing 41 is light emitting device 49 that is in the form of a fluorescent lamp, also known as an electrical discharge lamp, such as a compact fluorescent lamp. The light emitting device 49 includes a gas filled tube 62 and an electronic ballast 64 that is electrically connected to a cable (not shown) extended from the housing 42 of the light emitting device module 40. The electrically conductive cable is electrically connectable to the connector 54 of the retractable power cord 50 or to an electrical connector (not shown) mounted within the fascia 22 of the receptacle 20. Thus, that when the connector 14 of the power supply cable 12 is connected to a power supply electrical power is supplied to the light emitting device 49 of the light emitting device module 40. The light emitting device module 40 may include a switch to switch the light emitting device 49 on and off. The housing 42 of the light emitting device module 40 further includes a transparent cover 48 mounted to a free edge of the side panels 44, 45,46, 47 to thereby cover the light emitting device 49 and allow light to be transmitted there through.

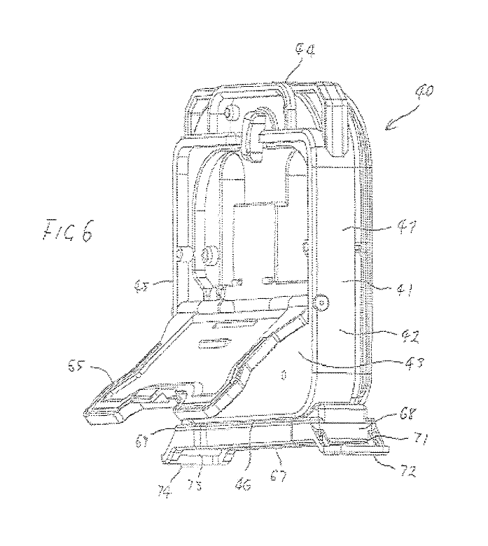

Referring to FIG. 6, the housing 42 of the light emitting device module 40 further includes a stand member 65 and a base panel 67. The base panel 67 is mounted to one of the side panels 44, 45, 46, 47 of the base housing 41 and the stand member 65 is pivotally connected to the base panel 43 of the base housing 41. In use, the light emitting device module 40 is mounted on a surface in an upright position and rests upon the base panel 67. The stand member 65 can be pivoted relative to the base housing 41 between a retracted position and an extended position wherein in the extended position the stand member 65 is operable for supporting the light emitting device module 40 in an upright position on a surface supported by the base panel 67. When the light emitting device module 40 is in the upright position the transparent cover 48 is orientated substantially transversely to the surface upon which the base panel 67 rests such that light emitted by the light emitting device 49 is transmitted through the transparent cover 48 reaches and illuminates a work area or a work surface.

The base panel 67 of the light emitting device module 40 includes a first end 68 and a second end 69 and an opening 71, 73 at each of the respective first and second ends 68, 69. Each of the openings 71, 73 includes an abutment surface 72, 74 located immediately adjacent to respective ones of the openings 71, 73. The facia 22 of the receptacle 20 includes a light emitting device module receiving opening 40A that is configured to receive the housing 42 of the light emitting device module 40 there through. When the housing 42 of the light emitting device module 40 is received through the opening 40A a pair of locking members 71 A, 73A are received through the openings 71, 73 and operate similarly to the locking members 37A, 39A described above for locking the power board module 30 to the receptacle 20. Accordingly, each of these locking members 71 A, 73A is a rotatable knob that is adapted to rotate to a position in which the locking members 71A, 73A abut against the abutment surfaces 72, 74 to lock the light emitting device module 40 within the opening 40A of the receptacle 20 and another position in which the light emitting device module 40 can be removed from the opening 40A of the receptacle 20.

Referring to FIGS. 1, 7 and 8, the power station assembly 10 is configured for attachment to a support 80 that is fixed to an upright surface such as a wall. The support 80 includes an elongate base 81 that is adapted to be fixed to a wall surface by any suitable means. The base 81 includes a plurality of apertures 82 adapted to receive fasteners there through to fix the base 81 to the wall surface. The support 80 further includes an interface part 83 that extends from the base 81. The interface part 83 includes a plurality of spaced apart upright members 84 that are upstanding from the base 81. The interface part 83 further includes an upper cross member 85 and a lower cross member 86 wherein both the upper and lower cross members 85, 86 extend between and are fixed to adjacent pairs of the upright members 84. The upper and lower cross members 85, 86 are spaced apart from the base 81. Furthermore, the upper and lower cross members 85, 86 respectively include an upper outwardly curved or convex surface 87 and a lower outwardly curved or convex curved surface 88. The receptacle 20 of the power station assembly 10 includes a pair of opposed inwardly curved, concave or hook shaped members 92, 94 within the base wall 23 of the base portion 21. The inwardly curved, concave or hook shaped members 92, 94 are spaced apart and oppose each other and define a recess 96 there between. The receptacle 20 of the power station assembly 10 is releasably mountable to the interface part 83 of the support 80 to thereby releasably mount the power station assembly 10 to the wall to which the support 80 is fixed. This is achieved by placing a first one of the inwardly curved, concave or hook shaped members 92 over one of the outwardly curved or convex surfaces 87, 88 of the upper and lower cross members 85, 86 and subsequently positioning the other one of the inwardly curved, concave or hook shaped members 92, 94 over the other one of the upper and lower outwardly curved or convex surfaces 87, 88 of the upper and lower cross members 85, 86. Thus, the inwardly curved, concave or hook shaped members 92, 94 abut against a respective one of the upper and lower outwardly curved or convex surfaces 87, 88 of the upper and lower cross members 85, 86 to thereby retain the upper and lower cross members 85, 86 within the recess 96 between the inwardly curved, concave or hook shaped members 92, 94. The weight of the assembly 10 is substantially supported by engagement between an upper one of the inwardly curved surfaces 92 of the receptacle 20 and an upper one of the outwardly curved surfaces 87 of the support 80. The receptacle 20 can pivot about the upper one of the inwardly curved surfaces 92 and the upper one of the outwardly curved surfaces 87 until a lower one of the inwardly curved surfaces 94 of the receptacle 20 engages the lower one of the outwardly curved surfaces 88 of the support 20 in a releasably locking arrangement such as in a snap fit manner.

When a user wishes to remove the power station assembly 10 from the support 80 the user can grip the receptacle 20 or the handle member 28 and remove the hook shaped members 92, 94 from the upper and lower cross members 85, 86. The user can then transport the power station assembly 10 to a location close to a power supply outlet where the user can connect the connector 14 of the power supply cord 12 to the power supply outlet. The user can then extend the retractable power cord 50 from the power station assembly 10 and bring the connector 54 of the retractable power cord 50 to a location at which the user wishes to use one or more electrically powered devices, such as hand held power tools, or where the user wishes to illuminate an area or work surface. The user can then connect the connector 54 of the retractable cable 50 to an electrically powered device at a location remote from the power station assembly 10. The user can then, as required, remove the power board module 30 from the power station assembly 10 and connect the electrical cable of the power board module 30 to the connector 54 of the retractable power cord 50 and also connect one or more electrically powered devices to the connector portions 36 of the power board module 30. The user can also remove the light emitting device module 40 from the power station assembly 10 and connect the power cord of the light emitting device module 40 to the connector 54 of the retractable power cord 50 or to a connector portion 36 of the power board module 30 and illuminate an area or a work surface.

After use, the user can return either the power board module 30 to the power board module receiving opening 30A of the receptacle 20 and/or can return the light emitting device module 40 to the light emitting device module receiving opening 40A of the receptacle 20. The user can then releasably lock the power board module 30 and the light emitting device module 40 thereto. The user can then return the power station assembly 10 to the support 80 and mount the power station assembly 10 to the interface part 83 of the support. 80

Finally, it is to be appreciated and understood that various alterations, modifications and/or additions may be introduced into the constructions and arrangements of the parts previously described without departing from the spirit or ambit of the invention.

1. An carry cabinet for providing electrical power to an electrical device, the carry cabinet comprising:
a receptacle including an electrical connector for connection to a power supply; and
a length of an electrical cable that is contained within the receptacle and that is coupled to the electrical connector;
wherein the length of electrical cable is retractably extendable from within the receptacle.

2. The carry cabinet of claim 1, wherein the electrical cable being electrically connectable to an electrically powered device to transmit electrical power from the power supply to the device.

3. The carry cabinet of claim 1, wherein the length of electrical cable is wound around a reel contained within the receptacle wherein the cable can be unwound from the reel to extend from the receptacle and wound around the reel to thereby retract the cable into the receptacle.

4. The carry cabinet of claim 1, wherein the carry cabinet further comprises a power distribution board including a housing having a plurality of electrical connectors for connection with one or more electrically powered devices and a length of electrical cable including an electrical connector for connection to a power supply.

5. The carry cabinet of claim 4, wherein the power distribution board and the receptacle are releasably connectable together and the receptacle includes an electrical connector that is connectable to the length of electrical cable of the power distribution board to supply electrical power thereto.

6. The carry cabinet of claim 4, wherein the receptacle comprises one or more releasable attachment means that are configured to releasably attach the housing of the power distribution board to the receptacle.

7. The carry cabinet of claim 6, wherein the one or more releasable attachment means include a rotatable abutment surface that is receivable through an opening in the housing of the power distribution board and is rotatable relative to the opening to a position in which the abutment surface abuts against a portion of the housing immediately adjacent to the opening to thereby lock the housing to the receptacle.

8. The carry cabinet of claim 1, wherein the carry cabinet further includes an electrically powered light emitting device that is releasably connectable to the receptacle and includes a length of electrical cable including an electrical connector for connection to a power supply.

9. The carry cabinet of claim 8, wherein the light emitting device includes a housing having a base member containing a light source and a transparent cover member connected to the base member for covering the light source and allowing light to pass therethrough.

10. The carry cabinet of claim 9, wherein the light emitting device housing comprises a stand member pivotally attached to the base member for maintaining the light emitting device in an upright position on a surface.

11. The carry cabinet of claim 8, wherein the receptacle comprises one or more releasable attachment means for releasably attaching the light emitting device to the receptacle.

12. The carry cabinet of claim 11, wherein the one or more releasable attachment means comprise a rotatable abutment surface that is receivable through an opening in the housing of the light emitting device and is rotatable relative to the opening to a position in which the abutment surface abuts against a portion of the housing immediately adjacent to the opening to thereby attach the housing to the receptacle.

13. The carry cabinet of claim 6, wherein the one or more releasable attachment means is suitable for attachment of the receptacle to a support fixed to an upright surface.

14. The carry cabinet of claim 13, wherein the receptacle comprises an opposing pair of curved members for receiving a pair of complementary curved surfaces of the support therebetween wherein the weight of the carry cabinet is substantially supported by engagement between an upper on of the curved members of the receptacle and an upper one of the curved surfaces of the support.

15. The carry cabinet of claim 14, wherein the receptacle pivots about the engaged upper one of the curved members and the upper one of the curved surfaces until a lower one of the curved members of the receptacle engages the lower one of the curved surfaces of the support in a releasable attachment arrangement.

16. A carry cabinet adapted for providing electrical power to an electrical device, such as a handheld power tool, the carry cabinet comprising:
an electrical connector for connection to a power supply; and
an electrical cable that is contained within the carry cabinet, the electrical cable having a first end for connection to the electrical connector and a second end that is electrically connectable to the electrical device to transmit electrical power from the power supply to the power tool;
wherein the carry cabinet includes a mounting mean for releasably mounting the cabinet on a frame.

17. The carry cabinet as claimed in claim 16, wherein the electrical device is the device is any one or any combination of a power tool, electromechanical device, kitchen, household or personal care electrical appliance, sander, power screwdriver, power drill, power saw, chainsaw, planer, router, grinder, polisher, rotary tool, light, powered knife, audio and/or visual device, computer, telephone.

18. The carry cabinet according to claim 16 wherein the mounting means comprises a latch and the carry cabinet can be changed between a mounted and a demounted configuration for portability, by respectively engaging and disengaging the latch between the carry cabinet and the frame.

19. The carry cabinet of claim 16 which further comprises an electrically powered light emitting device that is releasably connectable to the carry cabinet.

20. A storage system for storing devices comprising:
a frame for demountably supporting multiple carry cabinets,
at least one carry cabinet according claim 16,
at least one carry cabinet adapted to receive a handheld power tool, wherein said handheld power tools can be removably inserted through a port in their respective carry cabinet while said multiple carry cabinets are mounted on the frame,
characterised in that,
said devices can be transported in their respective carry cabinets when each of said carry cabinets are demounted from the frame and electrically connected to the electrical cable of the carry cabinet.
